(19) United States
(12) Patent Application Publication
(10) Pub. No.: US 2005/0158996 A1
(43) Pub. Date: Jul. 21, 2005

(54) Nickel salicide processes and methods of fabricating semiconductor devices using the same

(76) Inventors: Min-Joo Kim, Seoul (KR); Ja-Hum Ku, Seongnam-si (KR); Min-Chul Sun, Suwon-si (KR); Kwan-Jong Roh, Anyang-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/988,848

(22) Filed: Nov. 16, 2004

(30) Foreign Application Priority Data
Nov. 17, 2003 (KR) 2003-81255

(51) Int. Cl. H01L 21/322

(52) U.S. Cl. 438/664

(57) ABSTRACT

A nickel salicide process includes preparing a substrate having a silicon region and an insulating region containing silicon. Nickel is deposited on the substrate, and the nickel is annealed at a first temperature of 300° C. to 380° C. to selectively form a mono-nickel mono-silicide layer on the silicon region and to leave an unreacted nickel layer on the insulating region. The unreacted nickel layer is selectively removed to expose the insulating region and to leave the mono-nickel mono-silicide layer on the silicon region. Subsequently, the mono-nickel mono-silicide layer is annealed at a second temperature which is higher than the first temperature to form a thermally stable mono-nickel mono-silicide layer and without a phase transition of the mono-nickel mono-silicide layer.

### CROSS-REFERENCE TO RELATED APPLICATION

A claim of priority is made to Korean Patent Application No. 2003-81255, filed Nov. 17, 2003, the contents of which are hereby incorporated herein by reference in their entirety.

### BACKGROUND OF THE INVENTION

1. Field of the Invention

The present invention generally relates to methods of fabricating a semiconductor device and, more particularly, the present invention relates to nickel salicide processes and to methods of fabricating a semiconductor device using the same.

2. Description of the Related Art

Discrete devices such as metal oxide semiconductor (MOS) transistors are widely employed in semiconductor devices. As the semiconductor devices become more highly integrated, it becomes necessary to reduce the scale of the MOS transistors. The resultant reduction in channel length of the MOS transistors can cause a short channel effect. Also, reduction of the channel length leads to a narrowing of the width of the gate electrode, which in turn increases the electrical resistance of the gate electrode.

To improve upon the short channel effect, the thickness of the gate insulating layer as well as the junction depths of source and drain regions of the MOS transistor should be decreased. As a result, the capacitance (C) and the resistance (R) of the gate electrode may be increased. In this case, the transmission speed of an electrical signal applied to the gate electrode may be lowered by an increase in resistance-capacitance (RC) delay time.

In addition, the junction depths of the source/drain regions have been reduced in order to improve certain characteristics of the MOS transistors. In this case, however, the sheet resistances of the source/drain regions are increased, and the drivability of the short channel MOS transistor is degraded. As a result, a self-aligned silicide (salicide) technology has been widely employed in an effort to realize a high performance MOS transistor suitable for a highly integrated semiconductor device.

Salicide technology is a process technology for reducing the electrical resistance of the gate electrode and the source/drain regions by selectively forming a metal silicide layer on the gate electrode and the source/drain regions. A cobalt silicide layer and a titanium silicide layer have been employed as the metal silicide layer. Among these, the resistance of the cobalt silicide layer has a very low dependency on a change of line width. Accordingly, the cobalt silicide layer has been widely used as the metal silicide layer formed on the gate electrode of the short channel MOS transistor.

A method of forming a cobalt silicide layer is disclosed in U.S. Pat. No. 5,989,988 to linuma et al., entitled “Semiconductor Device And Method Of Manufacturing The Same.” However, when the width of the gate electrode is less than about 0.1 μm, limitations arise in the application of the cobalt suicide layer due to an agglomeration phenomenon. Accordingly, in recent years, nickel salicide technology has been used in the fabrication of high performance MOS transistors.

A nickel silicide layer formed by nickel salicide technology may exhibit diverse composition rates. For example, the nickel silicide layer may be any one of a di-nickel mono-silicide layer (Ni₂Si layer), a mono-nickel mono-silicide layer (NiSi layer) and a mono-nickel di-silicide layer (NiSi₂ layer). Among these, the NiSi layer has the lowest resistivity. Also, the NiSi layer is formed at a low temperature of about 300° C. to about 550° C.

A method of forming a nickel silicide layer and a cobalt silicide layer is disclosed in U.S. Pat. No. 5,780,361 to Inoue, entitled “Salicide Process For Selectively Forming A Monocobalt Disilicide Film On A Silicon Region”. According to Inoue, nickel is deposited on a silicon substrate at a temperature of 150° C. to 300° C. to form a di-nickel mono-silicide layer, and the di-nickel mono-silicide layer is annealed at a temperature higher than the deposition temperature to form a mono-nickel mono-silicide layer. In this case, when the mono-nickel mono-silicide layer is post-annealed at a temperature higher than about 600° C., the thermal instability of mono-nickel mono-silicide layer may result in its transformation into a mono-nickel di-silicide layer.

In conclusion, enhancement of the thermal stability of the mono-nickel mono-silicide layer is desired.

### SUMMARY OF THE INVENTION

Embodiments of the invention provide a nickel salicide process capable of enhancing the thermal stability of a mono-nickel mono-silicide layer.

Other embodiments of the invention provide a method of fabricating a semiconductor device which is thermally stabilized using a nickel salicide process.

In one aspect, the invention is directed to a nickel salicide process. The nickel salicide process includes preparing a substrate having a silicon region and an insulating region, and depositing nickel on the substrate. The substrate having the deposited nickel is annealed at a first temperature of 300° C. to 380° C. As a result, a mono-nickel mono-silicide layer is selectively formed on the silicon region, and an unreacted nickel layer remains on the insulating region. The unreacted nickel layer is selectively removed to expose the insulating region whereas the mono-nickel mono-silicide layer remains on the silicon region. The substrate in which the unreacted nickel layer is removed is annealed at a second temperature which is higher than the first temperature to thereby form a thermally stable mono-nickel mono-silicide layer and without a phase transition of the mono-nickel mono-silicide layer.

In some embodiments, the silicon region may be a single crystalline silicon substrate or a polysilicon layer, and the insulating region may be a silicon oxide layer or a silicon nitride layer.

In other embodiments, the nickel may be pure nickel or nickel alloy. The nickel--alloy-may contain at least one material selected from a group consisting of tantalum (Ta), zirconium (Zr), titanium (Ti), hafnium (Hf), tungsten (W), cobalt (Co), platinum (Pt), molybdenum (Mo), palladium (Pd), vanadium (V), and niobium (Nb).

In yet other embodiments, deposition of the nickel may be carried out at a temperature of 150° C. to 300° C. In addition, deposition of the nickel may be carried out using a sputtering technique.

In yet other embodiments, the second temperature may be in a range of 400° C. to 500° C. Annealing at the second temperature may be carried out using a sputtering apparatus or a rapid thermal annealing apparatus.

In another aspect, the invention is directed to a method of fabricating a semiconductor device using an optimized nickel salicide process. This method includes forming a transistor in a predetermined region of a semiconductor substrate. The transistor is formed to have a source region and a drain region spaced apart from each other, a gate pattern formed above a channel region between the source and drain regions, and an insulating spacer covering a sidewall of the gate pattern. Nickel is deposited on the entire surface of the semiconductor substrate having the transistor. A first annealing process is applied to the semiconductor substrate having the deposited nickel at a first temperature of 300° C. to 380° C. to selectively form a mono-nickel mono-silicide layer at least on the source and drain regions. In this case, an unreacted nickel layer remains on the insulating spacer. The unreacted nickel layer is selectively removed to expose the insulating spacer and to leave the mono-nickel mono-silicide layer on the source and drain regions. A second annealing process is applied to the semiconductor substrate where the unreacted nickel layer is removed at a second temperature which is higher than the first temperature to form a thermally stable mono-nickel mono-silicide layer and without a phase transition of the mono-nickel mono-silicide layer.

In some embodiments, forming the gate pattern includes forming a silicon layer on the semiconductor substrate and patterning the silicon layer. In this case, the patterned silicon layer reacts with nickel on the patterned silicon layer during the first annealing process to form the mono-nickel mono-silicide layer.

Alternatively, forming the gate pattern may include sequentially forming a conductive layer and an insulating layer on the semiconductor substrate, and simultaneously patterning the insulating layer and the conductive layer.

In other embodiments, the nickel may be pure nickel or nickel alloy. The nickel alloy may contain at least one material selected from a group consisting of Ta, Zr, Ti, Hf, W, Co, Pt, Mo, Pd, V, and Nb.

In yet other embodiments, deposition of the nickel may be carried out at a temperature of 150° C. to 300° C. In addition, deposition of the nickel may be carried out using a sputtering technique.

In yet other embodiments, the second temperature may be in a range of 400° C. to 500° C. Annealing at the second temperature may be carried out using a sputtering apparatus or a rapid thermal annealing apparatus.

In yet another aspect, the invention is directed to a method of fabricating a semiconductor device using an optimized nickel salicide process. This method includes forming a-transistor in a predetermined region of a semiconductor substrate. The transistor is formed to have a source region and a drain region spaced apart from each other, a gate electrode formed above a channel region between the source and drain regions, and an insulating spacer covering a sidewall of the gate electrode. An insulating mask pattern exposing the gate electrode is formed on the semiconductor substrate having the transistor. The insulating mask pattern is formed to cover the source and drain regions. Nickel is deposited on the entire surface of the semiconductor substrate having the mask pattern. A first annealing process is applied to the semiconductor substrate having the deposited nickel at a first temperature of 300° C. to 380° C. to selectively form a mono-nickel mono-silicide layer on the gate electrode. In this case, an unreacted nickel layer remains on the mask pattern. The unreacted nickel layer is selectively removed to expose the insulating mask pattern and to leave the mono-nickel mono-silicide layer on the gate electrode. A second annealing process is applied to the semiconductor substrate where the unreacted nickel layer is removed at a second temperature which is higher than the first temperature to form a thermally stable mono-nickel mono-silicide layer without a phase transition of the mono-nickel mono-silicide layer.

In some embodiments, the gate electrode may be formed of a silicon layer. In addition, the insulating spacer may be formed of a silicon oxide layer or a silicon nitride layer.

In other embodiments, forming the insulating mask pattern may include forming an insulating mask layer on the entire surface of the semiconductor substrate having the MOS transistor, and planarizing the insulating mask layer until the gate electrode is exposed. The insulating mask layer may be formed of a silicon oxide layer.

In yet other embodiments, the nickel may be pure nickel or nickel alloy. The nickel alloy may contain at least one material selected from a group consisting of Ta, Zr, Ti, Hf, W, Co, Pt, Mo, Pd, V, and Nb.

In yet other embodiments, deposition of the nickel may be carried out at a temperature of 150° C. to 300° C. In addition, deposition of the nickel may be carried out using a sputtering technique.

Furthermore, the second temperature may be in a range of 400° C. to 500° C.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawings are not necessarily to scale, with emphasis instead being placed upon illustrating the principles of the invention.

FIG. 1 is a process flow chart illustrating methods of fabricating a semiconductor device in accordance with embodiments of the present invention.

FIGS. 2 to 7 are cross-sectional views for explaining methods of fabricating a semiconductor device in accordance with embodiments of the present invention.

FIGS. 8 to 11 are cross-sectional views for explaining methods of fabricating a semiconductor device in accordance with other embodiments of the present invention.

FIG. 12 is a graph showing the thermal stability of nickel silicide layers fabricated in accordance with embodiments of the present invention and the thermal stability of conventional nickel silicide layers.

FIG. 13 is a graph showing sheet resistances of nickel suicide layers relative to the temperature of the first annealing process employed in embodiments of the present invention.

FIG. 14 is a graph showing the thermal stability of nickel silicide layers relative to pure nickel deposition temperatures.

FIG. 15 is a graph showing the thermal stability of nickel tantalum silicide layers relative to nickel-tantalum deposition temperatures.

FIG. 16 is a graph showing the thermal stability of nickel tantalum silicide layers formed on N-type impurity diffusion regions relative to nickel-tantalum deposition temperatures.

FIG. 17 is a graph showing the thermal stability of nickel tantalum silicide layers formed on P-type impurity diffusion regions relative to nickel-tantalum deposition temperatures.

FIG. 18 is a graph showing the thermal stability of nickel tantalum silicide layers formed on N-type polysilicon gate electrodes relative to line widths of the N-type polysilicon gate electrodes.

FIG. 19 is a graph showing the thermal stability of nickel tantalum silicide layers formed on P-type polysilicon gate electrodes relative to line widths of the P-type polysilicon gate electrodes.

FIG. 20 is a graph showing the thermal stability of nickel tantalum silicide layers formed on N-type impurity diffusion regions relative to line widths of the N-type impurity diffusion regions.

FIG. 21 is a graph showing the thermal stability of nickel tantalum silicide layers formed on P-type impurity diffusion regions relative to line widths of the P-type impurity diffusion regions.

FIG. 22 shows x-ray diffraction measurement results of nickel silicide layers relative to various nickel deposition temperatures.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the invention to those skilled in the art. In the drawings, the thicknesses and relative dimensions of layers and regions may be exaggerated for clarity. Like numbers refer to like elements throughout the drawings and specification.

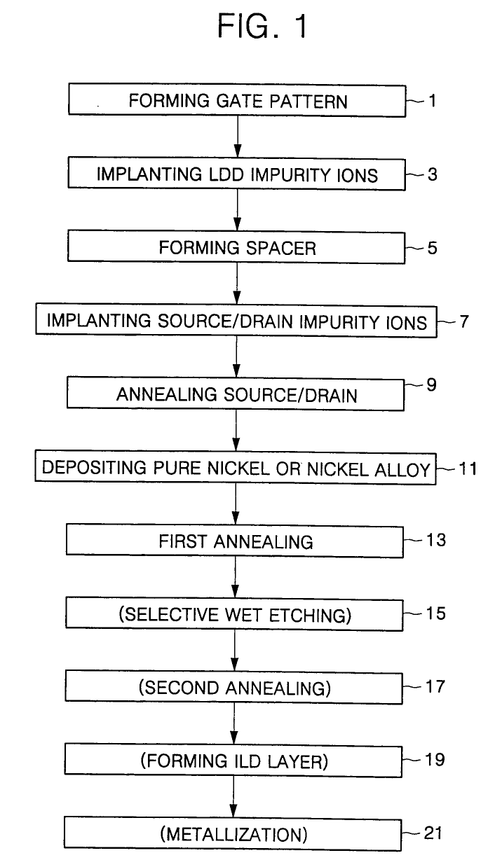

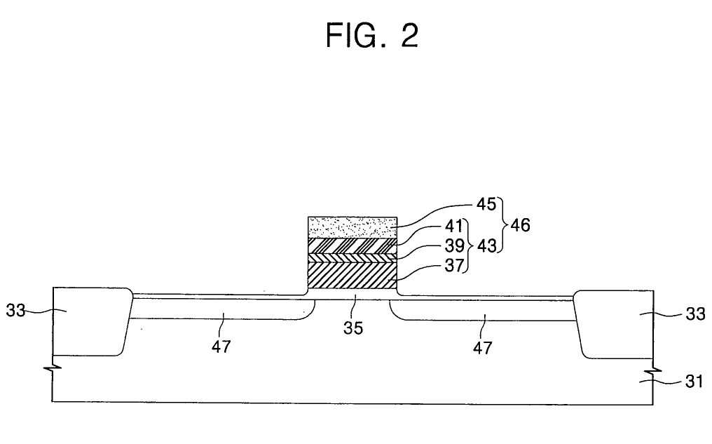

FIG. 1 is a process flow chart illustrating nickel salicide processes and methods of fabricating a semiconductor device using the same in accordance with embodiments of the present invention, and FIGS. 2 to 7 are cross-sectional views for explaining the nickel salicide processes and methods of fabricating a semiconductor device using the same in accordance with embodiments of the present invention.

Referring to FIG. 1, the processes of this embodiment initially include formation of a gate pattern (process 1), and implantation of low density diffusion (LDD) impurity ions (process 3).

That is, referring to FIG. 2, an isolation layer 33 is formed in a predetermined region of a semiconductor substrate 31, such as a single crystalline silicon substrate, to define an active region. A gate insulating layer 35 is formed on the active region. The gate insulating layer may, for example, be formed of a silicon oxide layer. A gate conductive layer (not shown) and a gate capping layer (not shown) are sequentially formed on the entire surface of the semiconductor substrate having the gate insulating layer 35. The gate conductive layer may, for example, be formed of any one of an amorphous silicon layer, a polysilicon layer, and a single crystalline silicon layer. If a silicon layer is adopted, it may be doped with N-type impurities or P-type impurities. Alternatively, the gate conductive layer may, for example, be formed by sequentially stacking a silicon layer, a tungsten nitride (WN) layer, and a tungsten layer. In this case, the silicon layer, the WN layer, and the tungsten layer may, for example, be formed to thicknesses of 800 Å, 50 Å, and 500 Å, respectively. In addition, the gate capping layer may, for example, be formed of an insulating layer such as a silicon oxide layer or a silicon nitride layer. The gate capping layer is considered optional and may be omitted.

The gate capping layer and the gate conductive layer are patterned to form a gate pattern 46 over the active region. As a result, the gate pattern 46 includes a gate electrode 43 and a gate capping layer pattern 45 which are sequentially stacked as shown in FIG. 2. However, if the gate capping layer is omitted, the gate pattern 46 may be composed of only the gate electrode 43. When the gate conductive layer is formed by sequentially stacking a silicon layer, a WN layer, and a tungsten layer, the gate electrode 43 includes a silicon pattern 37, a WN pattern 39, and a tungsten pattern 41 which are sequentially stacked. Alternatively, when the gate conductive layer is formed of only the silicon layer, the gate electrode 43 is composed of only the silicon pattern 37.

Subsequently, first impurity ions are implanted into the active region using the gate pattern 46 and the isolation layer 33 as ion implantation masks to thereby form lightly doped drain (LDD) regions 47. The first impurity ions may be N-type impurity ions or P-type impurity ions.

Referring again to FIG. 1, the processes of this embodiment further include formation of spacers (process 5), implantation of source/drain impurity ions (process 7), and source/drain anneal (process 7).

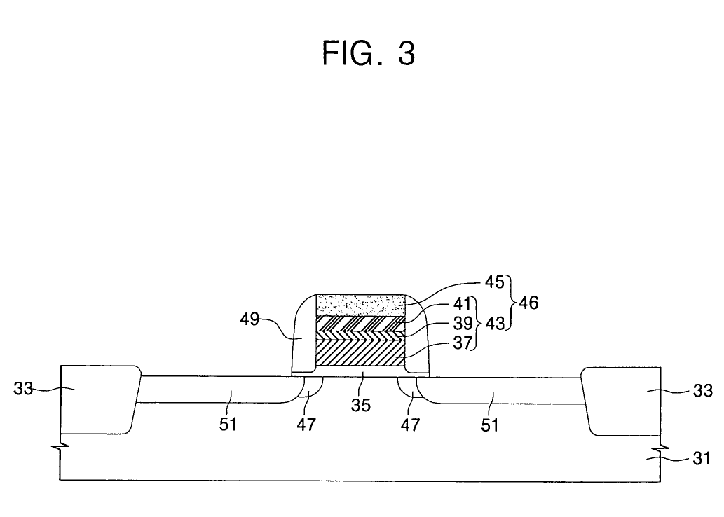

That is, as shown in FIG. 3, a spacer insulating layer (not shown) is formed on the entire surface of the semiconductor substrate having the LDD regions 47. The spacer insulating layer may, for example, be formed of a silicon oxide layer or a silicon nitride layer. The spacer insulating layer is then anisotropically etched to form an insulating spacer 49 on a sidewall of the gate pattern 46. Second impurity ions are implanted into the active region using the gate pattern 46, the spacer 49, and the isolation layer 33 as ion implantation masks to thereby form source and drain regions 51. As a result, the LDD regions 47 remain below the spacer 49. The second impurity ions may also be N-type impurity ions or P-type impurity ions.

The semiconductor substrate having the source and drain regions 51 is then annealed to activate the impurity ions within the source and drain regions 51. The source and drain annealing process may, for example, be performed by a rapid thermal annealing process at a temperature of 830° C. to 1150° C. The gate pattern 46, the gate insulating layer 35, the source and drain regions 51, and the spacer 49 constitute the MOS transistor. It is noted that formation of source and drain regions can be carried out using techniques other than those described above.

For example, methods can be adopted in which the source and drain regions protrude upwardly from the surface of the semiconductor substrate. In other words, elevated source and drain regions may be employed.

Referring again to FIG. 1, the processes of this embodiment further include deposition of a pure nickel or nickel alloy layer (process 11).

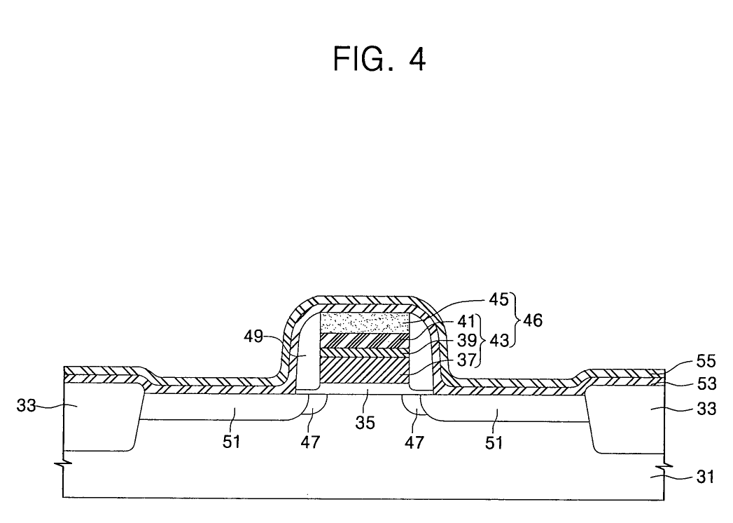

That is, referring to FIG. 4, the surface of the semiconductor substrate where the source and drain annealing process has been completed is cleaned to remove a native oxide layer and contaminated particles remaining on the source and drain regions 51. Nickel is then deposited on the entire surface of the cleaned semiconductor substrate. The nickel may be pure nickel or nickel alloy. If nickel alloy is used, the alloy may, for example, contain one or more of Ta, Zr, Ti, Hf, W, Co, Pt, Mo, Pd, V, and Nb. Use of nickel alloy may enhance the thermal stability of a nickel alloy silicide layer formed in a subsequent process.

It is preferable to deposit the nickel at a temperature of 150° C. to 300° C. In addition, the nickel may be deposited using a sputtering technique. The nickel may be deposited by forming a nickel layer 53, i.e., a pure nickel layer or a nickel alloy layer on the entire surface of the cleaned semiconductor substrate. In this case, silicon atoms within the source and drain regions 51 may react with nickel atoms within the nickel layer 53 during the nickel deposition. As a result, a di-nickel mono-silicide (Ni₂ Si) layer may be formed on the source and drain regions 51. However, the di-nickel mono-silicide layer still has a relatively high electrical resistance. A capping layer 55 may be further formed on the nickel layer 53. The capping layer 55 may be formed of a titanium nitride layer. In this case, the titanium nitride layer serves to prevent the nickel layer 53 from being oxidized. However, formation of the capping layer 55 may be omitted.

Referring again to FIG. 1, the processes of this embodiment further include a first annealing process (process 13).

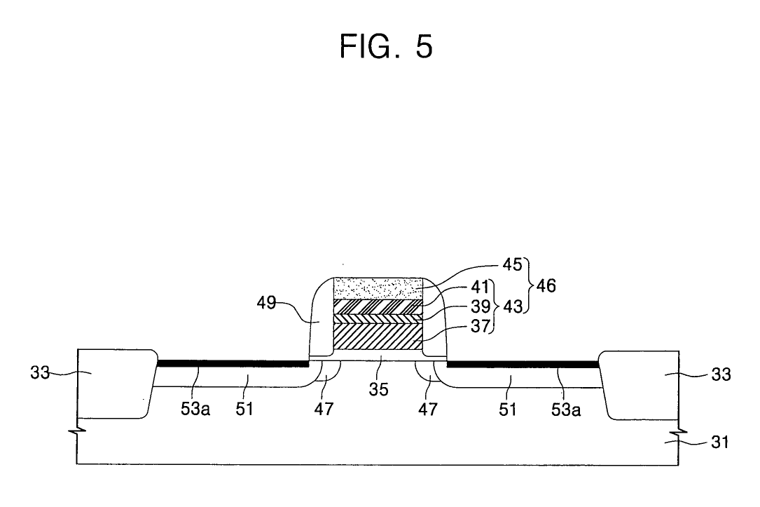

That is, referring to FIG. 5, a first annealing process is applied to the semiconductor substrate having the nickel layer 53 and the capping layer 55 (step 13 in FIG. 1). The first annealing process is preferably performed at a first temperature of about 300° C. to about 380° C. In this case, the nickel layer 53 on the source and drain regions 51 reacts with the silicon atoms within the source and drain regions 51 to form a mono nickel silicide layer 53a having a minimal electrical resistance. When the nickel is nickel tantalum, the mono-nickel mono-silicide layer 53a contains tantalum.

In the meantime, the insulating spacer 49, the gate capping layer pattern 45, and the isolation layer 33 do not react with the nickel layer 53 during the first annealing process. As a result, an unreacted nickel layer 53 remains on the insulating spacer 49, the gate capping layer pattern 45, and the isolation layer 33 even when the first annealing process is performed.

The first annealing process may be performed using a sputtering apparatus. That is, when the nickel is deposited using the sputtering apparatus, the first annealing process may be performed in-situ process after deposition of the nickel.

Referring again to FIG. 1, the processes of this embodiment further include a wet etching process (process 15).

That is, referring to FIG. 5, the unreacted nickel layer 53 is selectively removed using a wet etchant to expose the insulating spacer 49, the lo isolation layer 33, and the gate capping layer pattern 45. The unreacted nickel layer 53 may, for example, be removed using a mixture of sulfuric acid (H₂ SO₄) and hydrogen peroxide (H₂O₂). The capping layer 55 may also be stripped while the unreacted nickel layer is removed.

Referring yet again to FIG. 1, the processes of this embodiment further include a second annealing process (process 17), an ILD formation process (process 19), and a metallization process (process 21).

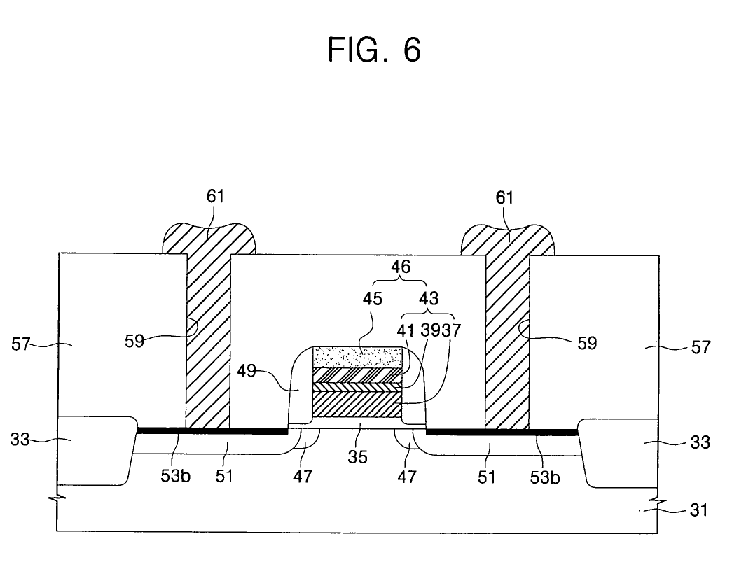

That is, referring to FIG. 6, a second annealing process is applied to the semiconductor substrate where the unreacted nickel layer 53 is removed (step 17 in FIG. 1). The second annealing process is preferably performed at a second temperature higher than the first temperature. In particular, the second temperature may be in a range of about 400° C. to about 500° C. In this case, the mono-nickel mono-silicide layers 53a on the source and drain regions 51 may be thermally stabilized without any phase transitions. As a result, mono-nickel mono-silicide layers 53b having thermal stability are formed on the source and drain regions 51. The second annealing process may be performed using a sputtering apparatus or a rapid thermal annealing apparatus.

An interlayer dielectric (ILD) layer 57 is formed on the semiconductor substrate after completion of the second annealing process. The ILD layer 57 is patterned to form contact holes 59 exposing the mono-nickel mono-silicide layers 53 b on the source and drain regions 51. A metal layer is formed on the entire surface of the semiconductor substrate having the contact holes 59, and the metal layer is patterned to form metal interconnection lines 61 covering the contact holes (step 21 in FIG. 1).

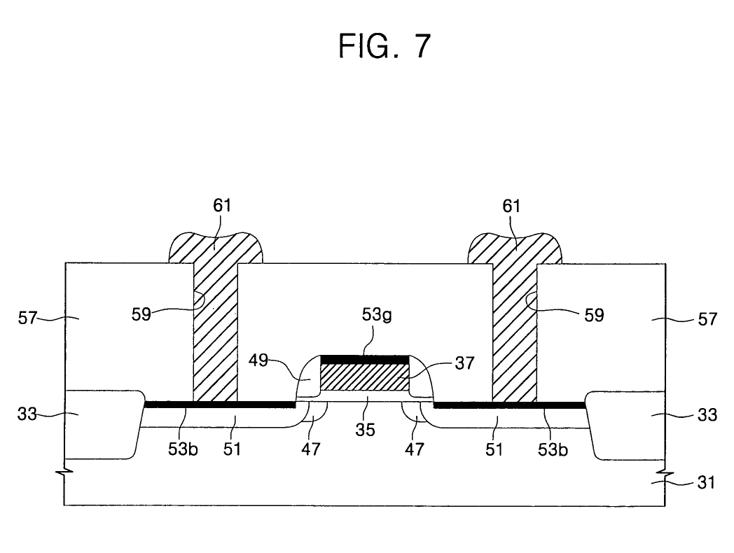

FIG. 7 is a cross-sectional view for explaining a method of fabricating a semiconductor device in accordance with other embodiment of the present invention. The present embodiment differs from the embodiments illustrated in FIGS. 2 to 6 with respect to the formation of the gate pattern.

Referring to FIG. 7, a silicon layer, for example, a polysilicon layer is formed on the entire surface of the semiconductor substrate having the gate insulating layer 35. The polysilicon layer is patterned to form a gate electrode crossing over the active region, i.e., a polysilicon pattern. In this case, the nickel layer 53 shown in FIG. 4 is formed to be in direct contact with the polysilicon pattern 37 as well as the source and drain regions 51. As a result, according to the present embodiment, not only is the mono-nickel mono-silicide layers 53b formed on the source and drain regions 51, but also a mono-nickel mono-silicide layer 53g is formed on the gate electrode 37 as shown in FIG. 7.

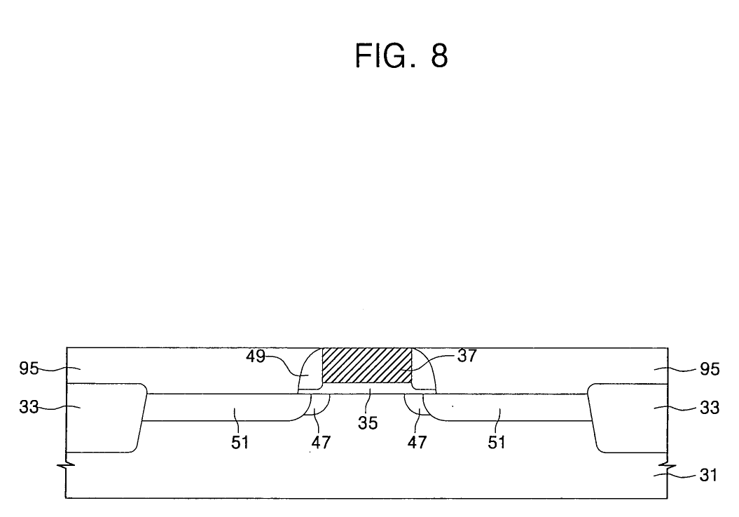

FIGS. 8 to 11 are cross-sectional views for explaining methods of fabricating a semiconductor device in accordance with other embodiments of the present invention.

Referring to FIG. 8, a MOS transistor is formed using the same methods as those described previously with reference to FIGS. 2 and 3. In the present embodiments, however, the gate pattern of the MOS transistor is formed to have only the silicon pattern 37. An insulating mask layer is then formed on the entire surface of the semiconductor substrate having the MOS transistor. Preferably, the insulating mask layer is formed of an insulating layer having an etch selectivity relative to the silicon pattern 37. For example, the insulating mask layer may be formed of a silicon oxide layer. The insulating mask layer is planarized to form an insulating mask pattern 95 exposing the silicon pattern 37. As a result, at least the source and drain regions 51 are covered with the mask pattern 95.

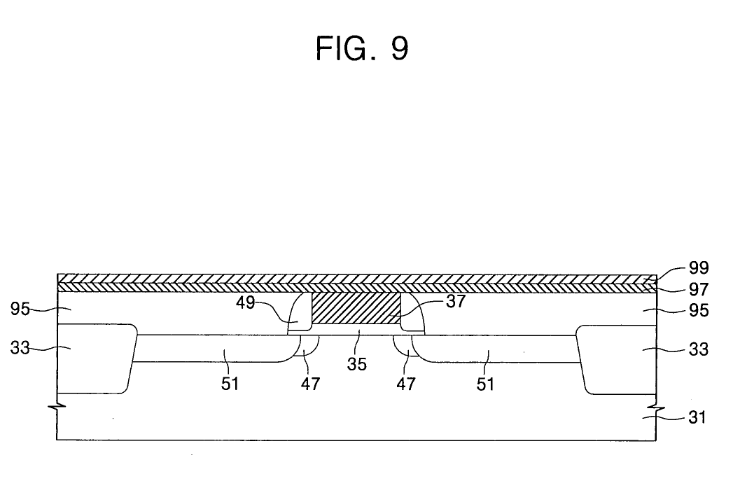

Referring to FIG. 9, nickel is deposited on the entire surface of the semiconductor substrate having the mask pattern 95. The nickel is deposited using the same method as that described previously with reference to FIG. 4. That is, the nickel may be pure nickel or nickel alloy, and is deposited at a temperature of 150° C. to 300° C. As a result, a nickel layer 97 is formed on the exposed silicon pattern 37 and the mask pattern 95. A capping layer 99 may be further formed on the nickel layer 97. The capping layer 99 is formed of the same material layer as the capping layer 55 shown in FIG. 4.

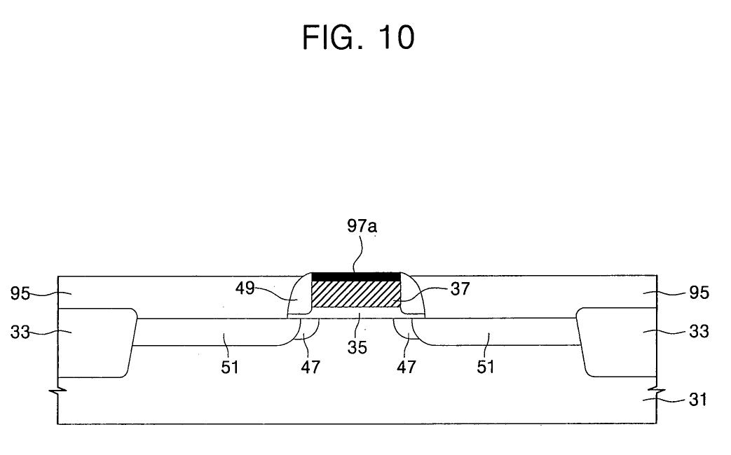

Referring to FIG. 10, a first annealing process is applied to the semiconductor substrate having the nickel layer 97 and the capping layer 99. The first annealing process is performed using the same method as that described previously with reference to FIG. 5. As a result, a mono-nickel mono-silicide layer 97 a is selectively formed only on the silicon pattern 37. An unreacted nickel layer 97 and the capping layer 99 remaining on the mask pattern 95 are then removed using a mixture of H₂SO₄ and H₂O₂.

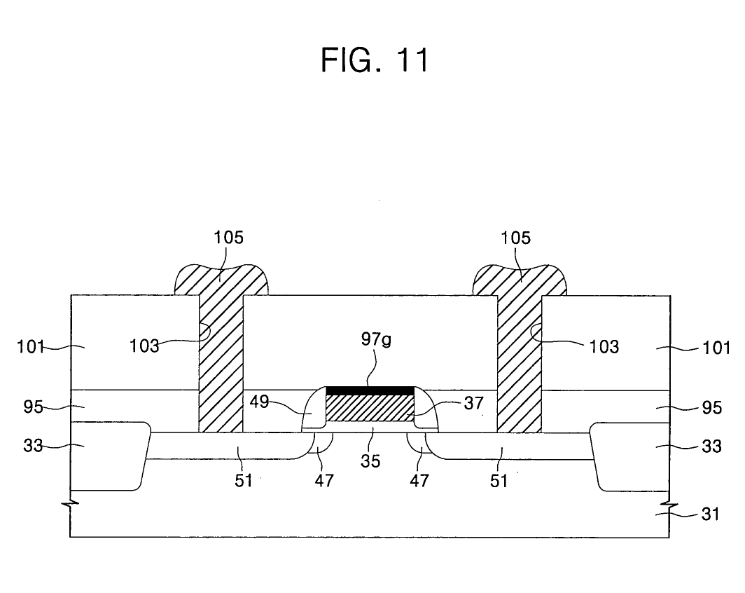

Referring to FIG. 11, a second annealing process is applied to the semiconductor substrate where the unreacted nickel layer 97 is removed. The second annealing process is performed using the same method as that described previously with reference to FIG. 6. As a result, a mono-nickel mono-silicide layer 97g having thermal stability is formed on the silicon pattern 37, i.e., the gate electrode.

An ILD layer 101 is formed on the semiconductor substrate after the second annealing process is completed. The ILD layer 101 and the mask pattern 95 are patterned to form contact holes 103 exposing the source and drain regions 51. Other contact holes exposing the mono-nickel mono-silicide layer 97g may be formed when the contact holes 103 are formed. A metal layer is formed on the entire surface of the semiconductor substrate having the contact holes 103, and the metal layer is patterned to form metal interconnection lines 105 covering the contact holes.

Hereinafter, various measurement results of samples fabricated in accordance with the above-mentioned embodiments and the prior art will be described.

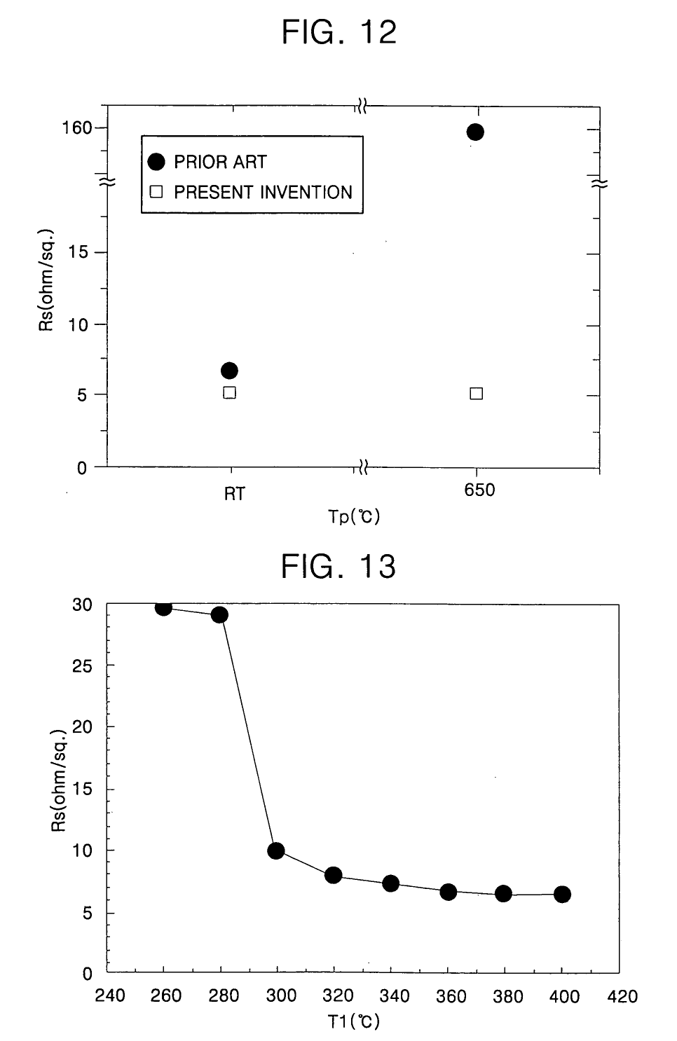

FIG. 12 is a graph showing the thermal immunity of mono-nickel mono-silicide layers fabricated in accordance with embodiments of the present invention and the prior art. Referring to FIG. 12, the horizontal axis indicates a post annealing temperature Tp, and the longitudinal axis indicates a sheet resistance Rs.

Mono-nickel mono-silicide layers exhibiting the measurement results of FIG. 12 were fabricated on a silicon substrate using key process conditions described in the following Table 1.

TABLE 1

| Process parameters | Prior art | Present invention |
|---|---|---|
| 1. Nickel deposition | Pure nickel, 300° C. | Pure nickel, 150° C. |
| 2. First annealing | Skipped | 300° C., 3 minutes |
| 3. Wet etching | Performed | Performed |
| 4. Second annealing | 450° C., 30 seconds, RTP | 430° C., 3 minutes, |
| | | Sputter annealing |

Referring to FIG. 12 and Table 1, both of the conventional mono-nickel mono-silicide layers and the mono-nickel mono-silicide layers of the present invention showed a sheet resistance of about 5 ohms/sq at a room temperature (RT). However, the conventional mono-nickel mono-silicide layers showed a high sheet resistance of about 160 ohms/sq after a post annealing process performed for 30 minutes at a temperature of 650° C. On the contrary, the mono-nickel mono-silicide layers of the present invention still showed a sheet resistance of 5 ohms/sq even after a post annealing process. Consequently, it may be recognized that the conventional mono-nickel mono-silicide layers are phase-transformed at a high temperature of 650° C. whereas the mono-nickel mono-silicide layers of the present invention are not phase-transformed even at a high temperature of 650° C. That is, the present invention enhances the thermal stability of the mono-nickel mono-silicide layers compared to the prior art.

FIG. 13 is a graph showing a sheet resistance of nickel silicide layers formed after the first annealing process described in Table 1. Referring to FIG. 13, the horizontal axis indicates a temperature T1 of the first annealing process, and the longitudinal axis indicates a sheet resistance Rs. In this case, the nickel silicide layers were formed by depositing pure nickel using a sputtering technique at a temperature of 150° C. and then annealing the pure nickel for 3 minutes.

As can be seen from FIG. 13, when the first annealing temperature T1 is lower than 300° C., the nickel silicide layers showed a sheet resistance of about 30 ohms/sq. On the contrary, when the first annealing temperature T1 is 300° C. or more, the sheet resistance of the nickel silicide layers was rapidly decreased to about 5 ohms/sq to about 10 ohms/sq. This may be understood to mean that the mono-nickel mono-silicide layer having the lowest electrical resistance is formed at a temperature of 300° C. or more.

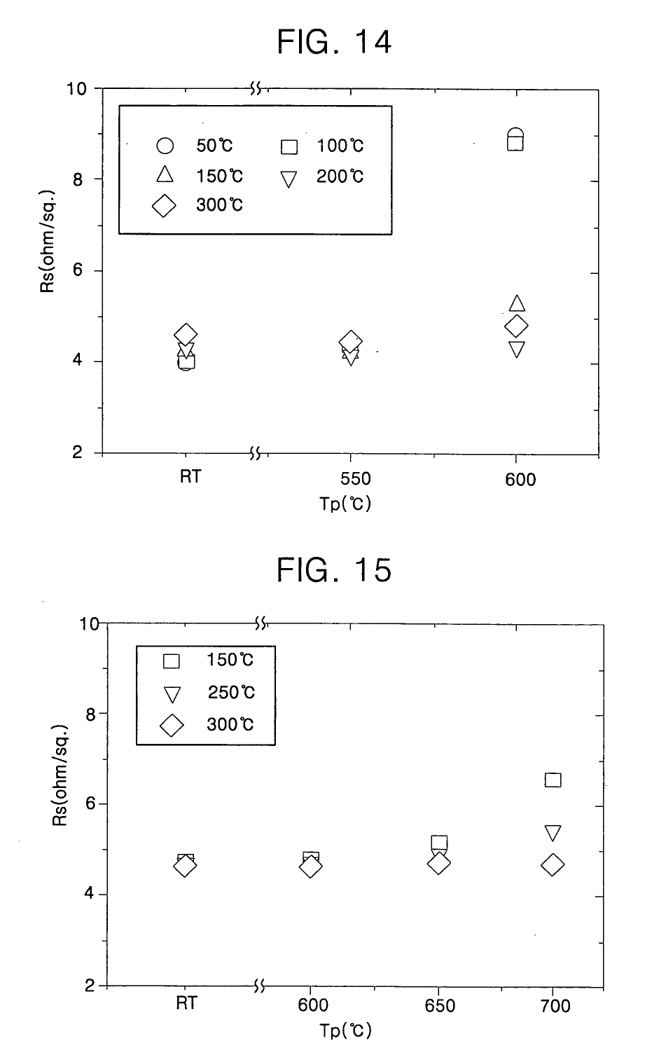

FIG. 14 is a graph showing the thermal stability of mono-nickel mono-silicide layers in response to deposition temperatures of pure nickel. Referring to FIG. 14, the horizontal axis indicates a post annealing temperature Tp and the longitudinal axis indicates a sheet resistance Rs.

Mono-nickel mono-silicide layers exhibiting the measurement results of FIG. 14 were fabricated on the silicon substrate using key process conditions described in the following Table 2.

TABLE 2

| Process | | | | | |
|---|---|---|---|---|---|
| Parameter | Sample A | Sample B | Sample C | Sample D | Sample E |
| Pure nickel | 50° C. | 100° C. | 150° C. | 200° C. | 300° C. |
| deposition | | | | | |

| | |
|---|---|
| First | 300° C., 3 minutes |
| annealing | |
| Wet etching | Performed |
| Second | 460° C., 30 seconds |
| annealing | |

Referring to FIG. 14 and Table 2, when the pure nickel was deposited at a temperature higher than about 150° C., mono-nickel mono-silicide layers showed a stable sheet resistance of about 5 ohms/sq even after a post annealing process was performed at about 600° C. On the contrary, when the pure nickel was deposited at a temperature of about 100° C. or less, the sheet resistance of the mono-nickel mono-silicide layers was rapidly increased to about 9 ohms/sq after a post annealing process was performed at about 600° C. Consequently, when the deposition temperature of the pure nickel is higher than about 100° C., thermally stable mono-nickel mono-silicide layers may be obtained.

FIG. 15 is a graph showing the thermal stability of mono-nickel mono-silicide layers in response to deposition temperatures of nickel tantalum (NiTa). Referring to FIG. 15, the horizontal axis indicates a post annealing temperature Tp and the longitudinal axis indicates a sheet resistance Rs. In this case, the nickel tantalum was deposited using a nickel tantalum target containing a tantalum content of 3.5 atomic %.

Mono-nickel mono-silicide layers exhibiting the measurement results of FIG. 15 were fabricated using the same annealing process conditions as those described above in Table 2.

Referring to FIG. 15, the mono-nickel mono-silicide layers showed a sheet resistance of about 4 ohms/sq to 6 ohms/sq even when the post annealing temperature was increased to 700° C. In particular, when the nickel tantalum was deposited at 300° C., the mono-nickel mono-silicide layers maintained a low sheet resistance of about 4.5 ohms/sq even after the post annealing process performed at 700° C. Consequently, a nickel alloy silicide layer containing tantalum showed a thermal stability superior to a pure nickel silicide layer.

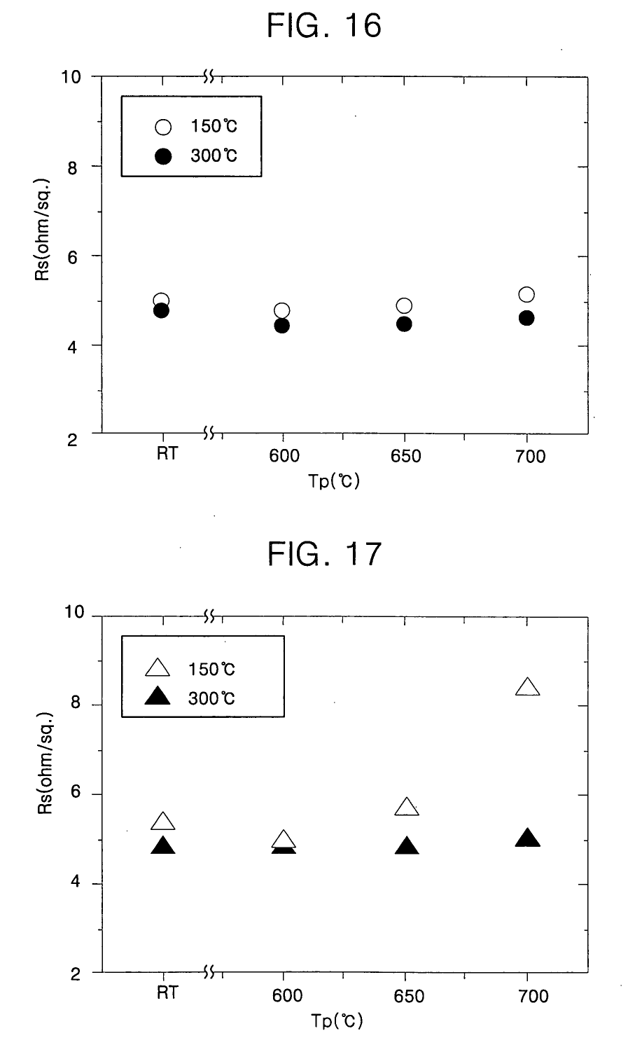

FIG. 16 is a graph showing the thermal stability of mono-nickel mono-silicide layers in response to deposition temperatures of nickel tantalum (NiTa) deposited on N-type impurity regions, and FIG. 17 is a graph showing the thermal stability of mono-nickel mono-silicide layers in response to deposition temperatures of nickel tantalum (NiTa) deposited on P-type impurity regions. Referring to FIGS. 16 and 17, each of the horizontal axes indicates a post annealing temperature Tp and each of the longitudinal axes indicates a sheet resistance Rs. In this case, the nickel tantalum was deposited using a nickel tantalum target containing a tantalum content of 3.5 atomic %. In addition, the N-type impurity regions were formed by implanting arsenic ions with a dose of 3×10¹⁵ atoms/cm² into the silicon substrate and then annealing the arsenic ions at 900° C., and the P-type impurity regions were formed by implanting boron ions with a dose of 3×10¹⁵ atoms/cm² into the silicon substrate and then annealing the boron ions at 900° C.

Mono-nickel mono-silicide layers exhibiting the measurement results of FIGS. 16 and 17 were fabricated using the same annealing process conditions as those described above in Table 2.

Referring to FIGS. 16 and 17, although the nickel tantalum was deposited at a low temperature of 150° C., mono-nickel mono-silicide layers formed on the N-type impurity regions showed a stable sheet resistance of about 5 ohms/sq after a post annealing process was performed at a high temperature of 700° C.

In the meantime, when the nickel tantalum was deposited at a low temperature of 150° C., mono-nickel mono-silicide layers formed on the P-type impurity regions showed a high sheet resistance of about 8.5 ohms/sq after a post annealing process was performed at a high temperature of 700° C. However, when the nickel tantalum was deposited at a high temperature of 300° C., the mono-nickel mono-silicide layers formed on both of the N-type impurity regions and the P-type impurity regions showed a stable sheet resistance of about 4 ohms/sq to about 5 ohms/sq even after the post annealing process was performed at a high temperature of 700° C.

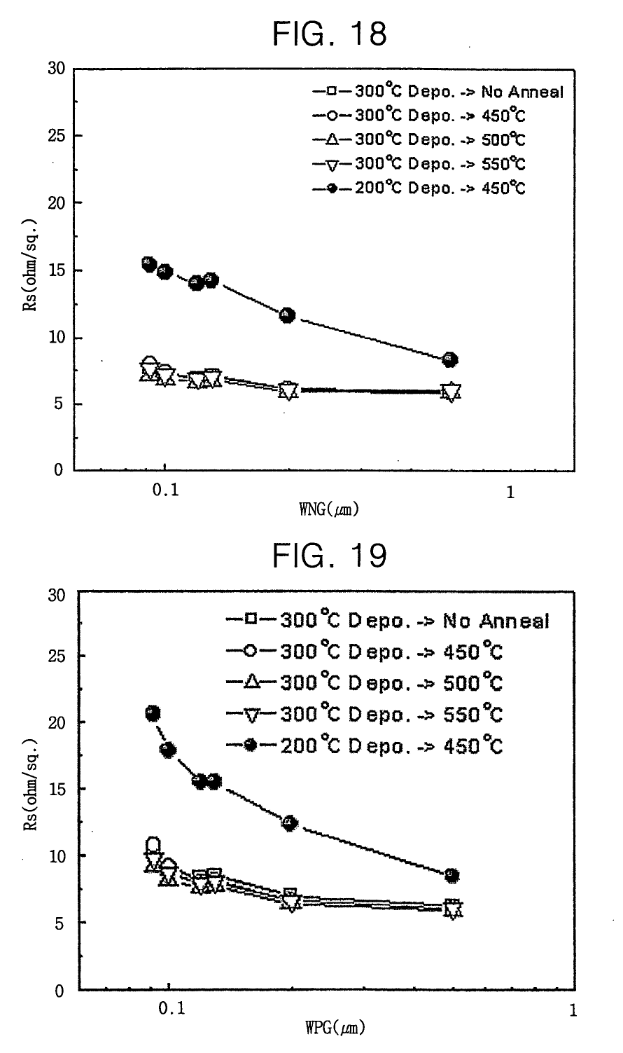

FIG. 18 is a graph showing the thermal stability of mono-nickel mono-silicide layers in response to post annealing temperatures and deposition temperatures of nickel tantalum deposited on N-type polysilicon gate electrodes having various widths, and FIG. 19 is a graph showing the thermal stability of mono-nickel mono-silicide layers in response to post annealing temperatures and deposition temperatures of nickel tantalum deposited on P-type polysilicon gate electrodes having various widths. Referring to FIG. 18, the horizontal axis indicates a width WNG of the N-type polysilicon gate electrodes, and the longitudinal axis indicates a sheet resistance Rs of mono-nickel mono-silicide layers formed on the N-type polysilicon gate electrodes. Similarly, referring to FIG. 19, the horizontal axis indicates a width WPG of the P-type polysilicon gate electrodes, and the longitudinal axis indicates a sheet resistance Rs of mono-nickel mono-silicide layers formed on the P-type polysilicon gate electrodes. In this case, the nickel tantalum was deposited using a nickel tantalum target containing a tantalum content of 3.5 atomic %.

Mono-nickel mono-silicide layers exhibiting the measurement results of FIGS. 18 and 19 were fabricated using the same annealing process conditions as those described above in Table 2.

Referring to FIGS. 18 and 19, when the nickel tantalum was deposited at a high temperature of 300° C., the mono-nickel mono-silicide layers formed on both of the N-type polysilicon gate electrodes and the P-type polysilicon gate electrodes showed a uniform sheet resistance of about 5 ohms/sq to about 10 ohms even after a post annealing process was performed at 550° C. In this case, although the widths WNG of the N-type polysilicon gate electrodes and the widths WPG of the P-type polysilicon gate electrodes were decreased to 0.09 μm, the mono-nickel mono-silicide layers formed on the polysilicon gate electrodes showed a stable sheet resistance of about 5 ohms/sq to about 10 ohms/sq.

Alternatively, when the nickel tantalum was deposited at a low temperature of 200° C., sheet resistances of the mono-nickel mono-silicide layers formed on the N-type polysilicon gate electrodes and the P-type polysilicon gate electrodes were rapidly increased after a post annealing process was performed at a low temperature of 450° C. In particular, the mono-nickel mono-silicide layers formed on the polysilicon gate electrodes having narrow widths of 0.09 μm showed a high sheet resistance of about 15 ohms/sq to about 20 ohms/sq.

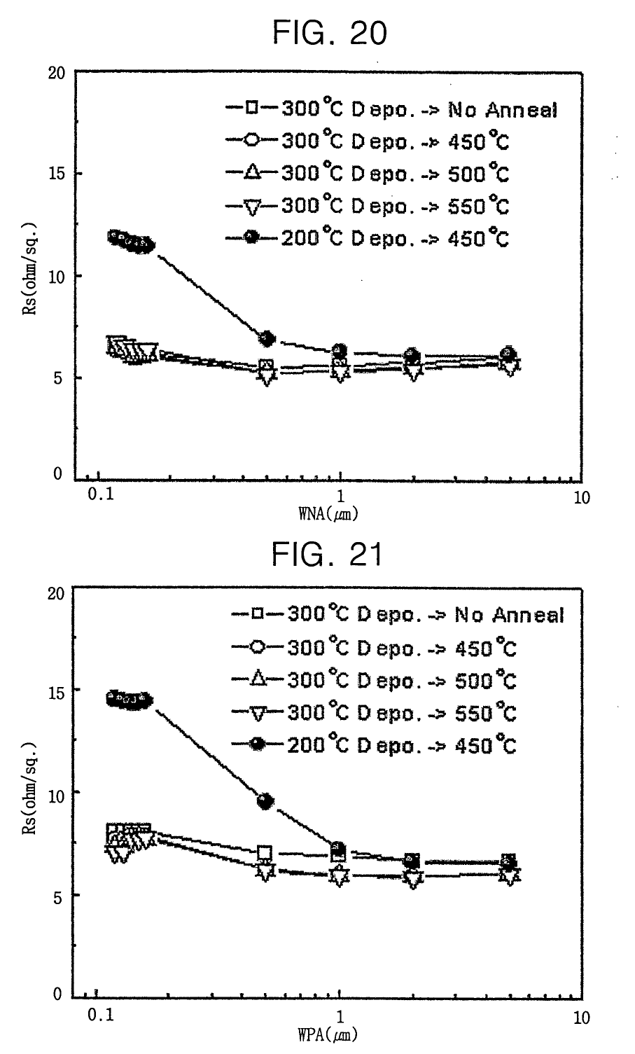

FIG. 20 is a graph showing the thermal stability of mono-nickel mono-silicide layers in response to post annealing temperatures and deposition temperatures of nickel tantalum (NiTa) deposited on the N-type active regions having various widths, and FIG. 21 is a graph showing the thermal stability of mono-nickel mono-silicide layers in response to post annealing temperatures and deposition temperatures of nickel tantalum (NiTa) deposited on the P-type active regions having various widths. Referring to FIG. 20, the horizontal axis indicates a width WNA of the N-type active regions, and the longitudinal axis indicates a sheet resistance Rs of mono-nickel mono-silicide layers formed on the N-type active regions. Similarly, referring to FIG. 21, the horizontal axis indicates a width WPA of the P-type active regions, and the longitudinal axis indicates a sheet resistance Rs of mono-nickel mono-silicide layers formed on the P-type active regions. In this case, the nickel tantalum was deposited using a nickel tantalum target containing a tantalum content of 3.5 atomic %. The N-type active regions and the P-type active regions were formed using the same methods as those of forming the N-type impurity diffusion regions described with reference to FIG. 16 and the P-type impurity diffusion regions described with reference to FIG. 17, respectively.

Mono-nickel mono-silicide layers exhibiting the measurement results of FIGS. 20 and 21 were fabricated using the same annealing process conditions as those described above in Table 2.

Referring to FIGS. 20 and 21, when the nickel tantalum was deposited at a high temperature of 300° C., the mono-nickel mono-silicide layers formed on both of the N-type active regions and the P-type active regions showed a uniform sheet resistance of about 5 ohms/sq to about 8 ohms/sq even after a post annealing process was performed at 550° C. In this case, although the widths WNA of the N-type active regions and the widths WPA of the P-type active regions were decreased to about 0.1 μm, the mono-nickel mono-silicide layers formed on the active regions showed a sheet resistance less than about 8 ohms/sq.

Alternatively, when the nickel tantalum was deposited at a low temperature of 200° C., sheet resistances of the mono-nickel mono-silicide layers formed on the N-type active regions and the P-type active regions were rapidly increased after a post annealing process was performed at a low temperature of 450° C. In particular, the mono-nickel mono-silicide layers formed on the active regions having narrow widths of 0.1 μm showed a high sheet resistance of about 12 ohms/sq to about 15 ohms/sq.

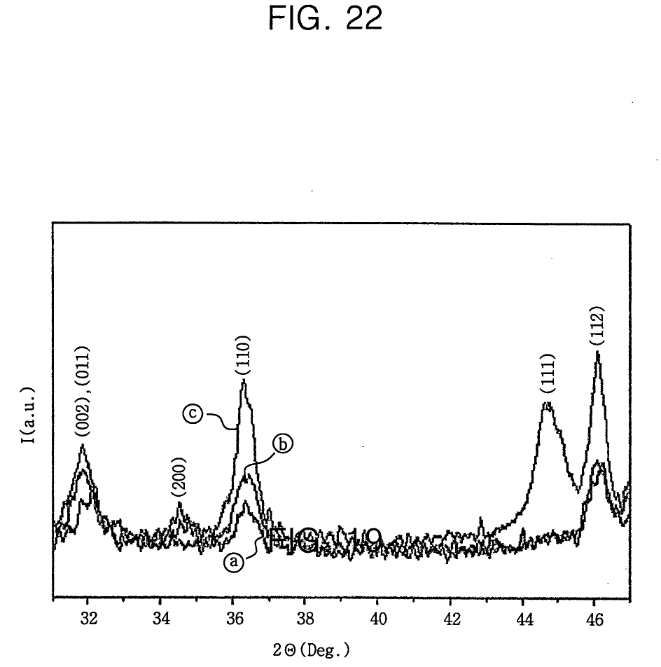

FIG. 22 shows x-ray diffraction measurement results of nickel silicide layers fabricated in response to various nickel deposition temperatures. Referring to FIG. 22, the horizontal axis indicates a diffraction angle of x-ray 2θ, and the longitudinal axis indicates an intensity I of the diffracted x-ray. Referring to FIG. 22, curve “a” indicates a measured result of samples in which the nickel was deposited at 300° C., curve “b” indicates a measured result of samples in which the nickel was deposited at 150° C., and curve “c” indicates a measured result of samples in which the nickel was deposited at 50° C. These samples were all fabricated using the same conditions as the annealing processes described above in Table 2.

As can be seen from FIG. 22, the nickel silicide layers formed at a low deposition temperature of 50° C., showed significant peaks at diffraction angles of about 36.5° and 44.5° after the second annealing process of Table 2 was performed. However, when the nickel silicide layers were formed at a high temperature of 300° C., these peaks were significantly decreased. These peaks represent the existence of a η-NiSi phase having an unstable phase. Consequently, it may be understood as that the η-NiSi phase present within the nickel silicide layer is decreased when the deposition temperature of the nickel is increased to thereby enhance the thermal stability of the nickel silicide layer.

According to the present invention as mentioned above, the nickel is deposited at a temperature of 150° C. to 300° C., and first and second annealing processes are performed at a first temperature of 300° C. to 380° C. and a second temperature higher than the first temperature, respectively. As a result, a thermally stable mono-nickel mono-silicide layer may be obtained.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A nickel salicide process, comprising:
providing a substrate having a silicon region and an insulating region;
depositing nickel on the substrate;
applying a first annealing process to the substrate at a first temperature of 300° C. to 380° C. to selectively react the nickel deposited on the silicon region to form a mono-nickel mono-silicide layer on the silicon region, wherein the nickel deposited on the insulating region is unreacted with the insulating region during the first annealing process such that unreacted nickel remains on the insulating region;
selectively removing the unreacted nickel to expose the insulating region, wherein the mono-nickel mono-silicide layer remains on the silicon region; and
applying a second annealing process to the substrate, after removal of the unreacted nickel, at a second temperature which is higher than the first temperature to form a thermally stable mono-nickel mono-silicide layer on the silicon region and without a phase transition of the mono-nickel mono-silicide layer.

2. The nickel salicide process as recited in claim 1, wherein the nickel is pure nickel or a nickel alloy.

3. The nickel salicide process as recited in claim 1, wherein the nickel is a nickel alloy which contains at least one material selected from the group consisting of tantalum (Ta), zirconium (Zr), titanium (Ti), hafnium (Hf), tungsten (W), cobalt (Co), platinum (Pt), molybdenum (Mo), palladium (Pd), vanadium (V), and niobium (Nb).

4. The nickel salicide process as recited in claim 1, wherein the nickel is deposited at a temperature of 150° C. to 300° C.

5. The nickel salicide process as recited in claim 4, wherein the nickel is deposited by sputtering.

6. The nickel salicide process as recited in claim 5, wherein the first annealing process is carried out in-situ after deposition of the nickel.

7. The nickel salicide process as recited in claim 1, wherein said selectively removing the unreacted nickel is carried out using a mixture of sulfuric acid and hydrogen peroxide.

8. The nickel salicide process as recited in claim 1, wherein the second temperature is in a range of 400° C. to 500° C.

9. The nickel salicide process as recited in claim 8, wherein the second annealing process is carried out using any one of a sputtering apparatus and a rapid thermal annealing apparatus.

10. The nickel salicide process as recited in claim 1, wherein the insulating region is formed of any one of a silicon oxide layer and a silicon nitride layer.

11. The nickel salicide process as recited in claim 1, wherein the silicon region is any one of a single crystalline silicon substrate and a polysilicon layer.

12. A method of fabricating a semiconductor device, comprising:
forming a transistor in a predetermined region of a semiconductor substrate, the transistor having a source region and a drain region spaced apart from each other, a gate pattern formed above a channel region between the source and drain regions, and an insulating spacer covering a side wall of the gate pattern;
depositing nickel on an entire surface of the semiconductor substrate having the transistor;
applying a first annealing process to the semiconductor substrate having the deposited nickel at a first temperature of 300° C. to 380° C. to selectively react the nickel deposited on the source and drain regions to form a mono-nickel mono-silicide layer on the source and drain regions, wherein the nickel deposited on the insulating spacer is unreacted with the insulating spacer such that unreacted nickel remains on the insulating spacer;
selectively removing the unreacted nickel layer to expose the insulating spacer, wherein the mono-nickel mono-silicide layer remains on the silicon region; and
applying a second annealing process to the semiconductor substrate, after removal of the unreacted nickel, at a second temperature which is higher than the first temperature to form a thermally stable mono-nickel mono-silicide layer on the source and drain regions and without a phase transition of the mono-nickel mono-silicide layer.

13. The method as recited in claim 12, wherein forming the gate pattern includes:
forming a silicon layer on the semiconductor substrate; and
patterning the silicon layer, wherein the patterned silicon layer reacts with the nickel deposited on the patterned silicon layer during the first annealing process to form the mono-nickel mono-silicide layer.

14. The method as recited in claim 12, wherein forming the gate pattern includes:
sequentially forming a conductive layer and an insulating layer on the semiconductor substrate; and
simultaneously patterning the insulating layer and the conductive layer.

15. The method as recited in claim 12, wherein the nickel is pure nickel or a nickel alloy.

16. The method as recited in claim 12, wherein the nickel is a nickel alloy which contains at least one material selected from a group consisting of tantalum (Ta), zirconium (Zr), titanium (Ti), hafnium (Hf), tungsten (W), cobalt *,(Co), platinum (Pt), molybdenum (Mo), palladium (Pd), vanadium (V), and niobium (Nb).

17. The method as recited in claim 12, wherein the nickel is deposited at a temperature of 150° C. to 300° C.

18. The method as recited in claim 17, wherein the nickel is deposited by sputtering.

19. The method as recited in claim 18, wherein the first annealing process is carried out in-situ after deposition of the nickel.

20. The method as recited in claim 12, wherein said selectively removing the unreacted nickel is carried out using a mixture of sulfuric acid and hydrogen peroxide.

21. The method as recited in claim 12, wherein the second temperature is in a range of 400° C. to 500° C.

22. The method as recited in claim 21, wherein the second annealing process is carried out using any one of a sputtering apparatus and a rapid thermal annealing apparatus.

23. The method as recited in claim 12, wherein the insulating spacer is formed of any one of a silicon oxide layer and a silicon nitride layer.

24. The method as recited in claim 12, further comprising forming an interlayer dielectric (ILD) layer on an entire surface of the semiconductor substrate after completion of the second annealing process.

25. A method of fabricating a semiconductor device, comprising:
forming a transistor in a predetermined region of a semiconductor substrate, the transistor having a source region and a drain region spaced apart from each other, a gate electrode formed above a channel region between the source and drain regions, and an insulating spacer covering a side wall of the gate electrode;
forming an insulating mask pattern exposing the gate electrode on the semiconductor substrate having the transistor, the insulating mask pattern covering the source and drain regions;
depositing nickel on an entire surface of the semiconductor substrate including the mask pattern;
applying a first annealing process to the semiconductor substrate having the deposited nickel at a first temperature of 300° C. to 380° C. to simultaneously form a mono-nickel mono-silicide layer on the gate electrode and to leave an unreacted nickel layer on the mask pattern;
removing the unreacted nickel layer to expose the insulating mask pattern and leaving the mono-nickel mono-silicide layer on the gate electrode; and
applying a second annealing process to the semiconductor substrate, in which the unreacted nickel layer is removed, at a second temperature which is higher than the first temperature to form a thermally stable mono-nickel mono-silicide layer on the gate electrode and without a phase transition of the mono-nickel mono-silicide layer.

26. The method as recited in claim 25, wherein the gate electrode is formed of a silicon layer.

27. The method as recited in claim 25, wherein the insulating spacer is formed of any one of a silicon oxide layer and a silicon nitride layer.

28. The method as recited in claim 25, wherein forming the insulating mask pattern includes:
forming an insulating mask layer on an entire surface of the semiconductor substrate having the transistor; and
planarizing the insulating mask layer until the gate electrode is exposed.

29. The method as recited in claim 28, wherein the insulating mask layer is formed of a silicon oxide layer.

30. The method as recited in claim 25, wherein the nickel is any one of pure nickel and nickel alloy.

31. The method as recited in claim 30, wherein the nickel is a nickel alloy which contains at least one material selected from a group consisting of tantalum (Ta), zirconium (Zr), titanium (Ti), hafnium (Hf), tungsten (W), cobalt (Co), platinum (Pt), molybdenum (Mo), palladium (Pd), vanadium (V), and niobium (Nb).

32. The method as recited in claim 25, wherein the nickel is deposited at a temperature of 150° C. to 300° C.

33. The method as recited in claim 32, wherein the nickel is deposited by sputtering.

34. The method as recited in claim 33, wherein the first annealing process is carried out in-situ after deposition of the nickel.

35. The method as recited in claim 25, wherein said selectively removing the unreacted nickel layer is carried out using a mixture of sulfuric acid and hydrogen peroxide.

36. The method as recited in claim 25, wherein the second temperature is in a range of 400° C. to 500° C.

37. The method as recited in claim 36, wherein the second annealing process is carried out using any one of a sputtering apparatus and a rapid thermal annealing apparatus.

38. The method as recited in claim 25, further comprising forming an interlayer dielectric (ILD) layer on an entire surface of the semiconductor substrate after completion of the second annealing process.
